(19) United States
(12) Patent Application Publication
(10) Pub. No.: US 2007/0069214 A1
(43) Pub. Date: Mar. 29, 2007

(54) Liquid crystal display and method of driving the same

(75) Inventor: Hyun Lee, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/528,041

(22) Filed: Sep. 27, 2006

(30) Foreign Application Priority Data
Sep. 29, 2005 (KR) 10-2005-0091402

(51) Int. Cl. H01L 29/04

(52) U.S. Cl. 257/72

(57) ABSTRACT

A liquid crystal display with reduced power consumption and a method of driving the same, in which a liquid crystal display includes a liquid crystal panel including a lower substrate and an upper substrate. The lower substrate has a display region with liquid crystal cells formed at intersections of a plurality of horizontally extending gate lines and a plurality of vertically extending data lines. The upper substrate has color filter regions formed at areas corresponding to the liquid crystal cells. The liquid crystal display includes a data driver for applying data signals to the plurality of data lines, such that the polarities of the data signals are inverted at intervals of at least three liquid crystal cells in a vertical direction and at intervals of one liquid crystal cell in a horizontal direction. The color filter regions adjacent to each other in the vertical direction are formed with color filters having different colors. Also provided is a method of driving the liquid crystal display. Thus, since the polarity patterns of the data signals are inverted at intervals of at least three liquid crystal cells so as to control the number of swings of the data signals, it is possible to reduce power consumption of the liquid crystal display.

### CROSS REFERENCE TO RELATED APPLICATION

This application claims priority to Korean Patent application No. 10-2005-0091402, filed on Sep. 29, 2005, and all the benefits accruing therefrom under 35 U.S.C. § 119, the contents of which are herein incorporated by reference in its entirety.

### BACKGROUND OF THE INVENTION

1. Technical Field

The present disclosure relates to a liquid crystal display and a method of driving the same, and more particularly, to a liquid crystal display with reduced power consumption and a method of driving the same.

2. Discussion of the Related Art

A liquid crystal display (LCD) displays an image thereon by controlling light transmissivity of liquid crystal cells in response to data signals, such as video signals. Such a liquid crystal display is implemented as an active matrix type having a switching device formed for each cell, and is used for the display device of a computer monitor, office equipment, cellular phone and the like. A thin film transistor (hereinafter, referred to as “TFT”) is used as a switching device of the active matrix type LCD.

Methods of driving such an LCD include inversion driving methods, such as a frame inversion system, a line inversion system and a dot inversion system.

In a liquid crystal panel driving method employing the frame inversion system, the polarity of a pixel data signal, which is applied to each of liquid crystal cells on a liquid crystal panel, is inverted every time a frame is changed. In a liquid crystal panel driving method employing the line inversion system, the polarity of a pixel data signal supplied to each of liquid crystal cells is inverted according to lines (columns) on a liquid crystal panel. In the dot inversion system, pixel data signals are applied such that the polarities of adjacent liquid crystal cells in one frame are opposite to each other, and then applied such that the polarities of liquid crystal cells in the next frame are opposite to those of the liquid crystal cells in the previous frame.

Among these inversion driving methods, the dot inversion system provides an image with superior quality as compared with the frame and line inversion systems.

Accordingly, in recent years, the dot inversion system has been primarily used. A one-dot inversion system in which the polarity of a pixel data signal is inverted on a one-dot basis has a problem of high power consumption, since the period of a pixel data signal, which is an output of a data driver, varies with a change in one gate line.

### SUMMARY OF THE INVENTION

Exemplary embodiments of the present invention are conceived to solve the aforementioned problems. Exemplary embodiments of the present invention provide a liquid crystal display and a method of driving the same, wherein the polarity patterns of data signals are inverted on an at least a three liquid crystal cell basis, thereby reducing power consumption.

A liquid crystal display of an exemplary embodiment of the present invention comprises a liquid crystal panel including a lower substrate and an upper substrate. The lower substrate has a display region with liquid crystal cells formed at intersections of a plurality of horizontally extending gate lines and a plurality of vertically extending data lines. The upper substrate has color filter regions formed at areas corresponding to the liquid crystal cells. The liquid crystal display comprises a data driver for applying data signals to the plurality of data lines such that the polarities of the data signals are inverted at intervals of at least three liquid crystal cells in a vertical direction and at intervals of one liquid crystal cell in a horizontal direction. The color filter regions adjacent to each other in the vertical direction are formed with color filters having different colors.

The color filter regions adjacent to each other in the horizontal direction are formed with color filters having an identical color.

The lower substrate may further comprise a peripheral region with a gate driver formed to apply gate signals to the plurality of gate lines. The liquid crystal display may further comprise a timing controller for controlling operations of the data driver and the gate driver using a synchronization signal, and for generating a polarity control signal for inverting the polarity of the data signal.

The gate driver includes a first gate driver connected to odd gate lines and a second gate driver connected to even gate lines, wherein the first gate driver and the second gate driver are formed in peripheral regions formed at left and right sides of the plurality of gate lines.

Moreover, a liquid crystal display of an exemplary embodiment of the present invention comprises a liquid crystal panel including a lower substrate and an upper substrate. The lower substrate has a display region with liquid crystal cells formed at intersections of a plurality of horizontally extending gate lines and a plurality of vertically extending data lines. The upper substrate has color filter regions formed at areas corresponding to the liquid crystal cells. The liquid crystal display comprises a data driver for applying data signals to the plurality of data lines such that the polarities of the data signals are inverted at intervals of at least three liquid crystal cells in a vertical direction and at intervals of one liquid crystal cell in a horizontal direction. The horizontal length of the liquid crystal cells is longer than the vertical length thereof.

The lower substrate further comprises a peripheral region with a gate driver formed to apply gate signals to the plurality of gate lines.

The liquid crystal display further comprises a timing controller for controlling operations of the data driver and the gate driver using a synchronization signal, and for generating a polarity control signal for inverting the polarity of the data signal.

The gate driver may include a first gate driver connected to odd gate lines and a second gate driver connected to even gate lines.

Furthermore, exemplary embodiments of the present invention provide a method of driving a liquid crystal display. The liquid crystal display comprises a liquid crystal panel including a lower substrate and an upper substrate. The lower substrate has a display region with liquid crystal cells formed at intersections of a plurality of horizontally extending gate lines and a plurality of vertically extending data lines and a peripheral region with a gate driver for applying gate signals to the plurality of gate lines. The upper substrate has color filters with different colors formed in areas facing the liquid crystal cells vertically adjacent to each other. A data driver applies data signals to the plurality of data lines. The method comprises the step of inverting the polarities of the data signals at intervals of at least three liquid crystal cells in the vertical direction and at intervals of one liquid crystal cell in the horizontal direction.

The method further comprises the steps of sequentially applying the gate signals to the gate lines so as to turn on a plurality of liquid crystal cells connected to one gate line, so that the data signals can be supplied to the liquid crystal cells; and inverting the polarities of the data signals after applying the gate signals at least three times.

The method further comprises the steps of (a) sequentially applying the gate signals to the gate lines so as to turn on a plurality of liquid crystal cells connected to one gate line; (b) applying a data signal with a first polarity to odd data lines and applying a data signal with a second polarity opposite to the first polarity to even data lines; and (c) inverting the polarities of the first and second data signals after performing the steps (a) and (b) at least three times.

### BRIEF DESCRIPTION OF THE DRAWINGS

Exemplary embodiments of the present invention will be understood in more detail from the following descriptions taken in conjunction with the accompanying drawings, in which:

FIG. 1 is a conceptual block diagram illustrating a liquid crystal display according to an exemplary embodiment of the present invention;

FIG. 2 is a view illustrating a method of driving a liquid crystal display according to an exemplary embodiment of the present invention;

FIG. 3 is a conceptual block diagram illustrating a liquid crystal display according to an exemplary embodiment of the present invention;

FIGS. 4 and 5 are views illustrating a method of driving a liquid crystal display according to an exemplary embodiment of the present invention; and

FIGS. 6 and 7 are views illustrating a method of driving a liquid crystal display according to an exemplary embodiment of the present invention.

### DETAILED DESCRIPTION OF EXEMPLARY EMBODIMENTS

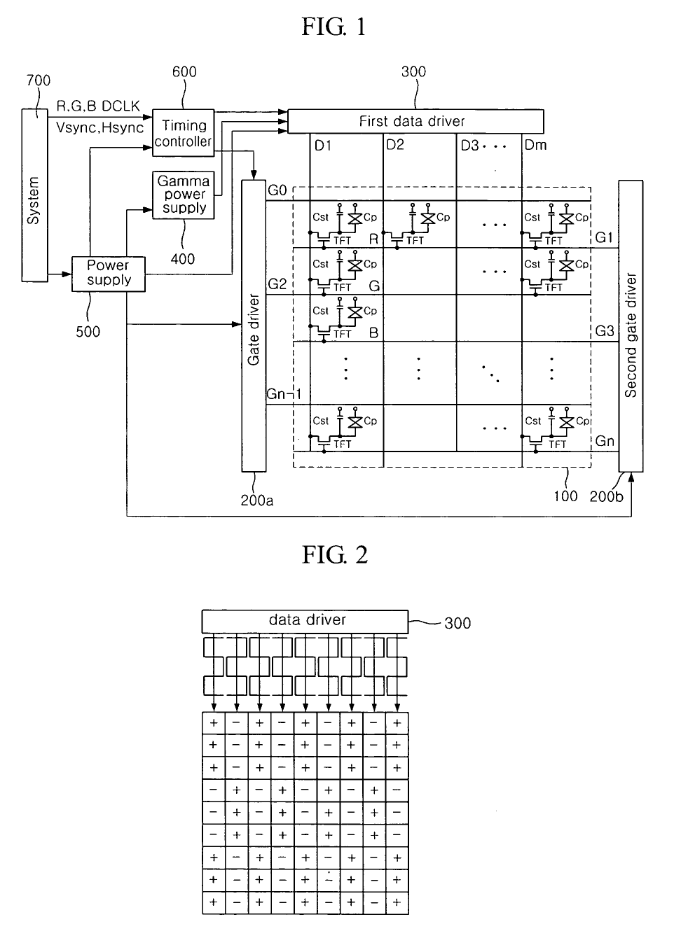

FIG. 1 is a conceptual block diagram illustrating a liquid crystal display according to an exemplary embodiment of the present invention.

Referring to FIG. 1, the liquid crystal display (LCD) comprises a liquid crystal panel 100 having m×n liquid crystal cells Cp arranged in a matrix pattern and TFTs formed at intersections of m data lines D1 to Dm and n gate lines G0 to Gn; a plurality of gate drivers 200a and 200b (collectively designated by 200) for supplying scan signals to the gate lines G0 to Gn of the liquid crystal panel; a data driver 300 for supplying data signals to the data lines D1 to Dm; a gamma voltage supply 400 for supplying a gamma voltage to the data driver 300; a power supply 500 supplying electric power to the gate driver 200 and the data driver 300 and the gamma power supply 400; and a timing controller 600 for controlling the data driver 300 and the gate driver 200 using synchronization signals Vsync and Hsync supplied from a system 700 and for supplying the data driver 300 with polarity control signals for inverting the polarities of data signals at intervals of at least three pixel cells. In addition, the LCD of this exemplary embodiment comprises a DC/DC converter (not shown) for increasing or decreasing a voltage input from the power supply 500 so as to generate a voltage to be supplied to the liquid crystal panel. At this time, the DC/DC converter generates a reference voltage for generation of a gamma voltage and a common voltage, a gate high voltage, a gate low voltage, and the like.

The system 700 supplies the timing controller 600 with the vertical/horizontal synchronization signals Vsync and Hsync, a clock signal DCLK, a date enable signal, video data signals R, G and B, and the like.

The liquid crystal panel 100 includes a lower substrate (not shown) and an upper substrate (not shown). The lower substrate is provided with a display region having the plurality of gate lines G0 to Gn, the plurality of data lines D1 to Dm, and the plurality of liquid crystal cells Cp formed at the intersections of the gate and data lines. The upper substrate is provided with a color filter region having a plurality of color filters (not shown) corresponding to the liquid crystal cells Cp.

The liquid crystal cells Cp include a pixel electrode, a common electrode corresponding thereto, and a liquid crystal provided between the two electrodes. The common electrode may be provided at the upper substrate.

The screen display region of the lower substrate further includes TFTs respectively connected to the plurality of pixel electrodes, and storage capacitors Cst for constantly maintaining the voltages of the liquid crystal cells Cp. The upper substrate further includes a black matrix for preventing light leakage.

Here, the TFTs supply data signals supplied from the data lines D1 to Dm to the liquid crystal cell Cp in response to scan signals supplied from the gate lines G0 to Gn.

At this time, a common voltage Vcom is supplied to the common electrodes that are part of each of the liquid crystal cells Cp.

In this exemplary embodiment, one pixel is defined by three liquid crystal cells Cp operated by three gate lines G0, G1 and G2 and one data line D1. At this time, it is preferred that color filters having different colors be continuously arranged on the liquid crystal cells Cp vertically adjacent to each other, and color filters having an identical color be arranged on the liquid crystal cells Cp horizontally adjacent to each other. The pixel exhibits a desired color by means of R, G and B color filters provided on the three liquid crystal cells Cp. That is, as shown in FIG. 1, an R color filter, a G color filter and a B color filter are provided in sequence on the liquid crystal cells Cp vertically adjacent to one another.

In order to exhibit a color by one pixel in this manner, the number of the gate lines is increased to three times but the number of the data lines is reduced to one third as compared with a conventional one. At this time, it is preferred that the horizontal length of the plurality of liquid crystal cells Cp be longer than the vertical length thereof. In this way, the vertical length of the liquid crystal panel 100 can be prevented from being increased.

In this exemplary embodiment, in response to data control signals from the timing controller 600, the data driver 300 supplies the respective data lines with pixel signals (data signals) the polarities of which are inverted at intervals of at least three gate lines. More specifically, the data driver 300 converts digital pixel data R, G and B, which are supplied from the timing controller 600, into analog pixel signals using a gamma voltage of a gamma voltage generator (not shown) and then supplies the analog pixel signals to the data line D1 and Dm.

Specifically, the data driver 300 sequentially receives and latches video data signals R, G and B on a predetermined unit basis using a source start pulse and a clock signal. After video data signals R, G and B corresponding to at least one line are latched, the video data signals R, G and B are simultaneously transmitted to a digital-to-analog signal converter (not shown) and converted into analog pixel signals using a gamma voltage. In this case, according to a polarity control signal supplied from the timing controller 600, the data driver 300 converts the polarities of positive and negative pixel data signals through a three-or-more-dot inversion before the supply thereof. A positive polarity can be defined as a voltage signal having a higher level than the common voltage Vcom, and a negative polarity can be defined as a voltage signal having a lower level than the common voltage Vcom. The data signal has an amplitude that is not greater than one third of the amplitude of the gate signal.

The gate driver 200 includes a first gate driver 200a connected to odd gate lines and a second gate driver 200b connected to even gate lines.

In response to gate control signals, the first and second gate drivers 200a and 200b sequentially supply a gate high voltage to the gate lines G0 to Gn. Accordingly, the gate driver 200 allows the thin film transistors connected to the gate lines G0 to Gn to be driven on a gate line basis. Specifically, according to a gate start pulse, a gate clock signal, a gate high voltage and a gate low voltage, the gate driver 200 supplies the gate high voltage to corresponding gate lines for every horizontal period H1, H2, . . . . In this case, the gate driver 200 supplies the gate high voltage only for an enable period, in response to a gate output enable signal. In addition, the gate driver 200 supplies the gate low voltage for other periods during which the gate high voltage is not supplied, and supplies the gate low voltage to remaining gate lines to which the gate high voltage is not supplied.

The gate driver 200 may be attached in the form of an IC at a peripheral region of the lower substrate of the liquid crystal panel 100, and may be formed directly at the peripheral region of the lower substrate. The peripheral region of the lower substrate can be provided at one side or both sides of the screen display region of the lower substrate.

In addition, the timing controller 600 generates control signals for controlling the gate driver 200 and the data driver 300, using the vertical/horizontal synchronization signals Vsync and Hsync and the clock signal DCLK input from the system 700. In this exemplary embodiment, the timing controller 600 generates the polarity control signal for alternately inverting the polarities of pixel data signals by at least three liquid crystal cells and supplies the polarity control signal to the data driver 300.

FIG. 2 is a view illustrating a method of driving a liquid crystal display according to an exemplary embodiment of the present invention.

Referring to FIG. 2, in this exemplary embodiment, the polarities of liquid crystal cells are inverted by means of the polarity control signal from the timing controller 600 such that positive and negative polarities alternate every third liquid crystal cell Cp in a vertical, that is, column, direction, but every cell Cp in a horizontal, that is, row, direction.

That is, in a case where liquid crystal cells are arranged in a 9×9 matrix pattern as illustrated in FIG. 2, a positive polarity (+) is applied to (1, 1) to (1, 3) and (1, 7) to (1, 9), and a negative polarity (−) is applied to (1, 4) to (1, 6). In addition, a negative polarity (−) is applied to (2, 1) to (2, 3) and (2, 7) to (2, 9), and a positive polarity (+) is applied to (2, 4) to (2, 6). In this way, positive and negative polarities alternate at intervals of one cell in the horizontal direction but alternate at intervals of three cells in the vertical direction.

The timing controller of this exemplary embodiment provides a polarity control signal so as to apply an identical polarity to respective groups each of which has three liquid crystal cells connected to one data line, and then generates and outputs a polarity control signal of which the polarity is contrary to that of the previous polarity control signal.

If three liquid crystal cells connected to one data line have a positive polarity (+), the next three liquid crystal cells have a negative polarity (−) and the next other three liquid crystal cells have a positive polarity (+).

More specifically, when a logic high gate signal (gate high voltage) is first applied in sequence to first to third gate lines, liquid crystal cells connected to the first to third gate lines are sequentially turned on. At this time, a data signal with a positive polarity (+) is applied to three liquid crystal cells connected to each of odd data lines, and a data signal with a negative polarity (−) is applied to three liquid crystal cells connected to each of even data lines. Thereafter, when a logic high gate signal is applied in sequence to fourth to sixth gate lines, liquid crystal cells connected to the fourth to sixth gate lines are sequentially turned on. At this time, a data signal with a negative polarity (−) is applied to three liquid crystal cells connected to each of odd date lines, and a data signal with a positive polarity (+) is applied to three liquid crystal cells connected to each of even data lines.

Polarities of data signals are inverted between adjacent data lines. Whenever gate signals are changed three times, the polarity of data signal of one data line is inverted. As such, a three-dot inversion method is implemented.

When the aforementioned driving method is carried out, power consumption of the liquid crystal display can be reduced. That is, if a conventional liquid crystal display consumes about 70 mW, a gate driver consumes about 20 mV, a data driver consumes about 40 mW and a logic circuit consumes about 10 mW. In the three-dot inversion mode of this exemplary embodiment, however, the power consumption of the data driver can be reduced by about 50% or more and thus it can be driven with 20 mW or less.

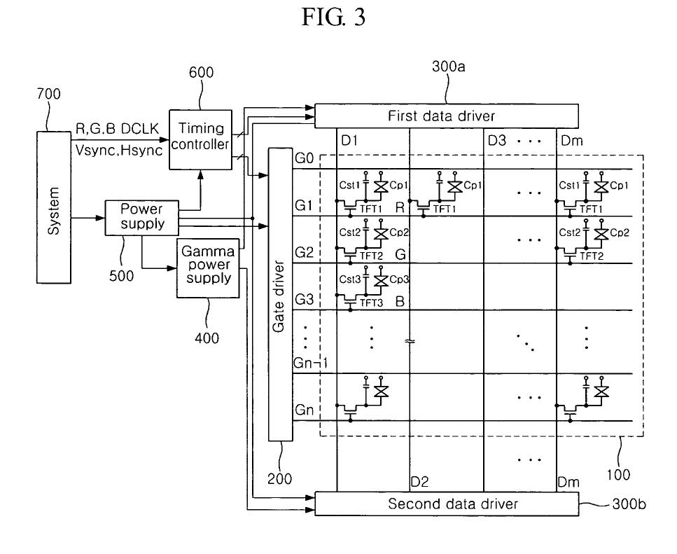

FIG. 3 is a conceptual block diagram illustrating a liquid crystal display according to an exemplary embodiment of the present invention.

Referring to FIG. 3, the LCD device of this exemplary embodiment comprises a liquid crystal panel 100 having m×n liquid crystal cells Cp arranged in a matrix pattern and TFTs formed at intersections of m data lines D1 to Dm and n gate lines G0 to Gn; a gate driver 200 for supplying scan signals to the gate lines G0 to Gn of the liquid crystal panel; a data driver 300a and 300b (collectively designated by 300) for supplying data signals to the data lines D1 to Dm; a gamma voltage supply 400 for supplying a gamma voltage to the data driver 300; a power supply 500 for supplying electric power to the drivers 200 and 300 and the gamma power supply 400; and a timing controller 600 for controlling the data driver 300 and the gate driver 200 using synchronization signals Vsync and Hsync supplied from the system 700 and for supplying the data driver with a polarity control signal for inverting the polarities of data signals for every at least three pixel cells.

The liquid crystal panel 100 has a plurality of liquid crystal cells Cp formed in a matrix pattern at intersections of the data lines D1 to Dm and the gate lines G0 to Gn. The TFTs connected to the liquid crystal cells Cp supply data signals, which are supplied from the data lines D1 to Dm, to the liquid crystal cells Cp, in response to scan signals supplied from the gate lines G0 to Gn. In addition, each of the liquid crystal cells Cp is provided with a storage capacitor Cst for constantly maintaining the voltage thereof for a certain period of time. A common voltage Vcom is supplied to a common electrode that is one electrode of each of the liquid crystal cells Cp. One pixel is defined by three liquid crystal cells driven by three gate lines G0, G1 and G2 and one data line D1. At this time, the three liquid crystal cells exhibit R, G and B colors, respectively. Accordingly, in this exemplary embodiment, the number of the gate lines is increased to three times but the number of the data lines D1 to Dn can be decreased. In addition, the longer axis of the plurality of liquid crystal cells Cp is formed in a matrix pattern at intersections of the data lines D1 to Dm and the gate lines G0 to Gn can be in a horizontal direction. This enables prevention of the vertical length of the liquid crystal panel 100 from being increased.

In this exemplary embodiment, the data driver 300 includes a first data driver 300a for applying pixel data signals to odd data lines and a second data driver 300b for applying pixel data signals to even data lines.

In response to data control signals from the timing controller 600, the first and second data drivers 300a and 300b supply the odd and even data lines with pixel signals (data signals), the polarities of which are inverted at intervals of at least three gate lines, respectively. More specifically, the data driver 300 converts digital video data signals R, G and B, which are supplied from the timing controller 600, into analog pixel signals using a gamma voltage from a gamma voltage generator (not shown) and supplies the analog pixel signals to the data line D1 and Dm.

Specifically, the data driver 300 sequentially receives and latches video data signals R, G and B on a predetermined unit basis, using a source start pulse and a clock signal. After video data signals R, G and B corresponding to at least one line are latched, the video data signals R, G and B are simultaneously transmitted to a digital-to-analog signal converter (not shown) and converted into analog pixel signals using the gamma voltage. In this case, according to a polarity control signal supplied from the timing controller 600, the first and second data drivers 300a and 300b convert the polarities of positive and negative pixel data signals through at least three-dot inversion before the supply thereof. A positive polarity can be defined as a voltage signal having a higher level than the common voltage Vcom, and a negative polarity can be defined as a voltage signal having a lower level than the common voltage Vcom.

The gate driver 200 sequentially supplies a gate high voltage to the gate lines G0 to Gn, in response to gate control signals from the timing controller 600.

In this exemplary embodiment, the timing controller 600 generates a polarity control signal for inverting the data polarity pattern of a pixel data signal on an at least a three liquid crystal cell basis and supplies the polarity control signal to the data driver 300. At this time, since the data driver 300 is divided into the first and second data drivers 300a and 300b according to the odd and even lines, the polarity control signal is divided into first and second polarity control signals. In addition, the first and second polarity control signals can be applied as having opposite polarities. That is, the second polarity control signal is an inverted one of the first polarity control signal.

Hereinafter, methods of driving the liquid crystal displays having the aforementioned configurations according to exemplary embodiments of the present invention will be described.

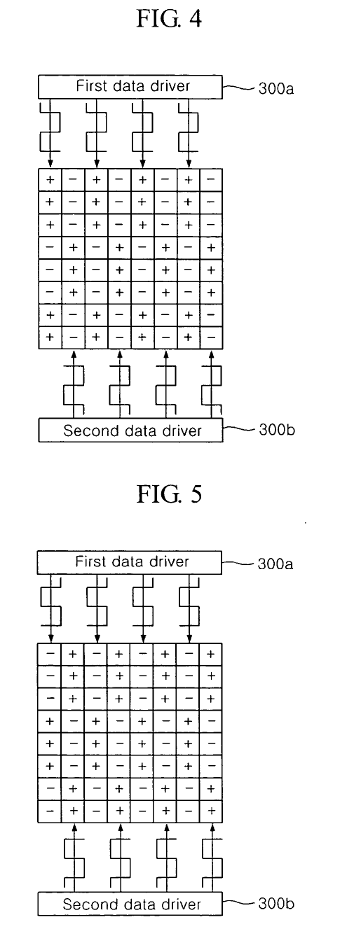

FIGS. 4 and 5 are views illustrating a method of driving a liquid crystal display according to an exemplary embodiment of the present invention.

Referring to FIGS. 4 and 5, in this exemplary embodiment, the polarities of liquid crystal cells are inverted by means of the polarity control signal from the timing controller 600 such that positive and negative polarities alternate every third liquid crystal cell Cp in a vertical, that is, column, direction, but every cell Cp in a horizontal, that is, row, direction.

That is, in a case where liquid crystal cells are arranged in an 8×8 matrix pattern as illustrated in FIG. 4, a positive polarity (+) is applied to (1, 1) to (1, 3) and (1, 7) to (1, 8), and a negative polarity (−) is applied to (1, 4) to (1, 6). In addition, a negative polarity (−) is applied to (2, 1) to (2, 3) and (2, 7) to (2, 8), and a positive polarity (+) is applied to (2, 4) to (2, 6). In this way, positive and negative polarities alternate at intervals of one cell in the row direction but alternate at intervals of three cells in the column direction.

The timing controller 600 of this exemplary embodiment provides a polarity control signal so as to apply an identical polarity to respective groups each of which has three liquid crystal cells connected to one data line, and then generates and outputs a polarity control signal of which the polarity is contrary to that of the previous polarity control signal. If three liquid crystal cells connected to one data line have a positive polarity (+), the next three liquid crystal cells have a negative polarity (−) and the next other three liquid crystal cells have a positive polarity (+). At this time, the timing controller 600 generates a first polarity control signal and a second polarity control signal inverted therefrom, and applies the first polarity control signal to the first data driver 300a and the second polarity control signal to the second data driver 300b. In this way, the first polarity signal applied to the first data driver 300a is applied to odd data lines connected to the first data driver 300a, and the second polarity control signal applied to the second data driver 300b is applied to even data lines connected to the second data driver 300b. Accordingly, in a case where three liquid crystal cells connected to the first data line have a positive polarity (+), three liquid crystal cells connected to second data line adjacent to the first data line have a negative polarity (−).

More specifically, when a logic high gate signal (gate high voltage) is first applied in sequence to first to third gate lines, the liquid crystal cells connected to the first to third gate lines are sequentially turned on. At this time, a data signal with a positive polarity (+) is applied to three liquid crystal cells connected to each of the odd data lines connected to the first data driver 300a, and a data signal with a negative polarity (−) is applied to three liquid crystal cells connected to each of the even data lines connected to the second data driver 300b. Thereafter, when a logic high gate signal is applied in sequence to fourth to sixth gate lines, the liquid crystal cells connected to the fourth to sixth gate lines are sequentially turned on. At this time, a data signal with a negative polarity (−) is applied to three liquid crystal cells connected to each of the odd data lines connected to the first data driver 300a, and a data signal with a positive polarity (+) is applied to three liquid crystal cells connected to each of the even data lines to the second data driver 300b.

That is, whenever the gate signals are changed three times, the status of the polarity control signal of the timing controller 600 is inverted so that polarities of data signals of one data line can be inverted. In addition, the polarity control signal is applied to the first and second data drivers to invert polarities of data signals of odd and even data lines, thereby implementing a three-dot inversion method.

Exemplary embodiments of the present invention are not limited to the foregoing. The polarity inversion period of the polarity control signal may be controlled such that the polarity inversion method can be applied to more than three liquid crystal cells. That is, other methods such as a four-dot inversion method, a five-dot inversion method and the like may be implemented.

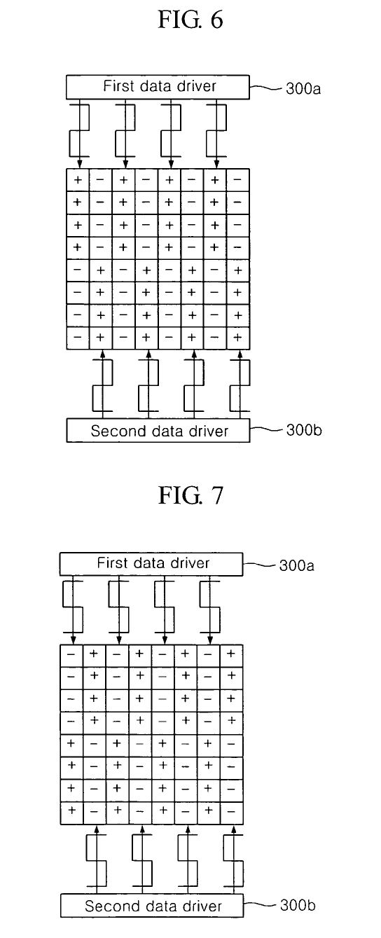

FIGS. 6 and 7 are views illustrating a method of driving a liquid crystal display according to an exemplary embodiment of the present invention.

Referring to FIGS. 6 and 7, the widths of data signals applied from the first and second data drivers 300a and 300b are controlled such that positive and negative polarities are inverted at intervals of four liquid crystal cells Cp in a vertical direction and at intervals of one liquid crystal cell Cp in a horizontal direction.

That is, in case of liquid crystal cells Cp electrically connected to odd data lines, which receive data signals from the first data driver 300a, the polarities of the data signals are inverted every fourth data period. In case of liquid crystal cells Cp electrically connected to even data lines, which receive data signals from the second data driver 300b, the polarities of the data signals are inverted every fourth data period. In addition, the polarities of data signals output from the first and second data driver 300a and 300b are inverted from each other.

At this time, the first and second data drivers 300a and 300b apply data signals to the data lines according to the polarity control signals from the timing controller 600. Thus, the period of liquid crystal cell Cp at which its polarity is inverted can be controlled by controlling the period of the polarity control signal from the timing controller 600.

More specifically, when a logic high gate signal is applied in sequence to first to fourth gate lines, the liquid crystal cells connected to the first to fourth gate lines are sequentially turned on. At this time, a signal with a positive polarity (+) is applied to four liquid crystal cells connected to each of the odd data lines connected to the first data driver 300a, and a signal with a negative polarity (−) is applied to four liquid crystal cells connected to each of the even data lines connected to the second data driver 300b. Thereafter, when a logic high gate signal is applied in sequence to fifth to eighth gate lines, the liquid crystal cells connected to the fifth to eighth gate lines are sequentially turned on. At this time, a signal with a negative polarity (−) is applied to four liquid crystal cells connected to each of the odd data lines connected to the first data driver 300a, and a signal with a positive polarity (+) is applied to four liquid crystal cells connected to each of the even data lines connected to the second data driver 300b.

Whenever the gate signals are changed four times as such, the status of the polarity control signal of the timing controller 600 is inverted and thus the polarities of data signals applied to the data lines are inverted. In addition, control signals with different polarities are applied respectively to odd and even data lines through different data drivers, thereby implementing the four-dot inversion method.

Of course, the present invention is not limited to the foregoing exemplary embodiments. As described in connection with an exemplary embodiment, the period of the polarity control signal of the timing controller may be controlled to implement the three-dot inversion method, the four-dot inversion method, and the like.

As described above, according to exemplary embodiments of the present invention, the number of swings of data lines are reduced to achieve reduction in power consumption of the entire device. That is, if the polarities of liquid crystal cells are inverted every one cell as in a conventional one, the number of voltage swings of data signals that vary in the data driver is eight in total. As shown in FIGS. 6 and 7, however, in a case where the polarity is changed at intervals of four liquid crystal cells, the number of voltage swings of data signals, which are changed through a data driver, is two in total, that is, they are significantly decreased. Thus, if the polarities of liquid crystal cells are inverted at intervals of n cells, there is an advantage in that the number of swings can be reduced by 1/n times, thereby reducing power consumption.

Further, the present invention is not limited to the foregoing exemplary embodiments. That is, the operation of the aforementioned configuration may be applied to a liquid crystal display where a plurality of gate lines extend in a vertical direction and data lines extend in a horizontal direction.

As described above, according to exemplary embodiments of the present invention, the polarities of data signals can be inverted on an at least three liquid crystal cell basis, thereby reducing power consumption of a liquid crystal display.

Although the present invention has been described in connection with exemplary embodiments illustrated in the accompanying drawings, it is not limited thereto but defined by the appended claims. It will be readily understood by those skilled in the art that various modifications and changes can be made thereto without departing from the spirit and scope of the present invention defined by the appended claims.

What is claimed is:

1. A liquid crystal display, comprising:
a liquid crystal panel including a lower substrate and an upper substrate, the lower substrate having a display region with liquid crystal cells formed at intersections of a plurality of horizontally extending gate lines and a plurality of vertically extending data lines, the upper substrate having color filter regions formed at areas corresponding to the liquid crystal cells; and
a data driver for applying data signals to the plurality of data lines such that polarities of the data signals are inverted at intervals of at least three liquid crystal cells in a vertical direction and at intervals of one liquid crystal cell in a horizontal direction,
wherein the color filter regions adjacent to each other in the vertical direction are formed with color filters having different colors.

2. The liquid crystal display as claimed in claim 1, wherein the color filter regions adjacent to each other in the horizontal direction are formed with color filters having an identical color.

3. The liquid crystal display as claimed in claim 1, wherein the lower substrate further comprises a peripheral region with a gate driver formed to apply gate signals to the plurality of gate lines.

4. The liquid crystal display as claimed in claim 3, further comprising a timing controller for controlling operations of the data driver and the gate driver using a synchronization signal, and for generating a polarity control signal for inverting the polarity of the data signal.

5. The liquid crystal display as claimed in claim 3, wherein the gate driver includes a first gate driver connected to odd gate lines and a second gate driver connected to even gate lines.

6. The liquid crystal display as claimed in claim 5, wherein the first gate driver and the second gate driver are formed in peripheral regions formed at left and right sides of the plurality of gate lines.

7. A liquid crystal display, comprising:
a liquid crystal panel including a lower substrate and an upper substrate, the lower substrate having a display region with liquid crystal cells formed at intersections of a plurality of horizontally extending gate lines and a plurality of vertically extending data lines, the upper substrate having color filter regions formed at areas corresponding to the liquid crystal cells; and
a data driver for applying data signals to the plurality of data lines such that polarities of the data signals are inverted at intervals of at least three liquid crystal cells in a vertical direction and at intervals of one liquid crystal cell in a horizontal direction,
wherein a horizontal length of the liquid crystal cells is longer than a vertical length thereof.

8. The liquid crystal display as claimed in claim 7, wherein the lower substrate further comprises a peripheral region with a gate driver formed to apply gate signals to the plurality of gate lines.

9. The liquid crystal display as claimed in claim 8, further comprising a timing controller for controlling operations of the data driver and the gate driver using a synchronization signal, and for generating a polarity control signal for inverting the polarity of the data signal.

10. The liquid crystal display as claimed in claim 8, wherein the gate driver includes a first gate driver connected to odd gate lines and a second gate driver connected to even gate lines.

11. A method of driving a liquid crystal display, the liquid crystal display including a liquid crystal panel including a lower substrate and an upper substrate, the lower substrate having a display region with liquid crystal cells formed at intersections of a plurality of horizontally extending gate lines and a plurality of vertically extending data lines and a peripheral region with a gate driver for applying gate signals to the plurality of gate lines, the upper substrate having color filters with different colors formed in areas facing the liquid crystal cells vertically adjacent to each other, and a data driver for applying data signals to the plurality of data lines, the method comprising the step of:
inverting polarities of the data signals at intervals of at least three liquid crystal cells in a vertical direction and at intervals of one liquid crystal cell in a horizontal direction.

12. The method as claimed in claim 11, further comprising the steps of:
sequentially applying the gate signals to the gate lines so as to turn on a plurality of liquid crystal cells connected to one gate line so that the data signals can be supplied to the liquid crystal cells; and
inverting the polarities of the data signals after applying the gate signals at least three times.

13. The method as claimed in claim 11, further comprising the steps of:
(a) sequentially applying the gate signals to the gate lines so as to turn on a plurality of liquid crystal cells connected to one gate line;
(b) applying a data signal with a first polarity to odd data lines and applying a data signal with a second polarity opposite to the first polarity to even data lines; and
(c) inverting the polarities of the first and second data signals after performing the steps (a) and (b) at least three times.
